(19) United States
(12) Patent Application Publication
(10) Pub. No.: US 2024/0393368 A1
(43) Pub. Date: Nov. 28, 2024

(54) PROBE SYSTEM FOR TESTING OF DEVICES UNDER TEST INTEGRATED ON A SEMICONDUCTOR WAFER, AND PROBE CARD, PROBE HEAD, AND GUIDING PLATE STRUCTURE THEREIN

(71) Applicant: MPI CORPORATION, Hsinchu (TW)

(72) Inventors: CHIN-TIEN YANG, Hsinchu (TW); YU-HAO CHEN, Hsinchu (TW); HUI-PIN YANG, Hsinchu (TW); CHI-HSIEN LI, Hsinchu (TW)

(21) Appl. No.: 18/645,531

(22) Filed: Apr. 25, 2024

Related U.S. Application Data
(60) Provisional application No. 63/462,947, filed on Apr. 28, 2023.

(51) Int. Cl. G01R 1/067; G01R 1/073

(52) U.S. Cl. CPC G01R 1/06755; G01R 1/06733; G01R 1/07342

(57) ABSTRACT

A probe system and a probe card, a probe head and a guide plate structure thereof are described herein. The probe head includes a plurality of probes and guide plates. Each probe includes a first end, a second end, and a probe body. The first end is configured to abut a contact pad of the device under test. The second end is configured to abut a contact pad of a board of the probe system. The probe body extends between the first end and the second end according to a longitudinal development axis. The guide plate includes a pair of first guide holes for a pair of probes to pass through, and the pair of first guide holes are configured to slidably accommodate the pair of probes. The material between the pair of first guide holes in the guide plate has a relative dielectric constant not greater than 6, so as to reduce the return loss between the probe head and the device under test.

### CROSS-REFERENCES TO RELATED APPLICATIONS

This application claims priority to U.S. Provisional Application No. 63/462,947 filed on Apr. 28, 2023, the contents of which are incorporated herein by reference.

### BACKGROUND OF THE INVENTION

The present invention relates to a probe head and a guide plate structure in the probe head. More specifically, the present invention relates to a probe head and a guide plate structure thereof which reduce the return loss between a probe card comprising the probe head and a device under test.

As a tool for testing the electrical properties of a semiconductor wafer or a packaged device, a probe card may generally comprise at least a probe head, a space transformer and a circuit board. The probe head may comprise a plurality of probes, and each of the plurality of probes may contact with a device under test (DUT) integrated in a semiconductor wafer to test the electrical performance of the device under test.

In recent years, the demand for high-frequency/high-speed testing of electronic devices under test is increasing day by day, and with the increase of data transmission rate during testing (e.g., from 50 to 60 Gigabits per second (Gbps) to more than 100 Gbps), the influence of impedance matching between the probe head as a whole and the device under test on high-speed signal transmission has become more significant. When the impedance of the test path (that is, the signal transmission path) is not matched, the influence of return loss will become significant.

However, since the probe head not only comprises electronic components but also comprises non-electronic components (e.g., probes and guide plates) together, mechanical characteristics of these components must be taken into account in the design of impedance matching thereof. Because it involves different types of components and the influence of the mechanical structure needs to be considered in the electrical design, such design is more difficult than the space transformer and the wiring substrate (e.g. printed circuit board, PCB) disposed thereon. Accordingly, an urgent need exists in the art to improve the degree of impedance matching between the probe head as a whole and the device under test.

### SUMMARY OF THE INVENTION

In order to at least solve the above technical problems, the present invention provides a guide plate structure of a probe head of a probe system for testing a device under test integrated in a semiconductor wafer. The guide plate structure may comprise a first guide plate. The first guide plate may comprise a pair of first guide holes for a pair of probes of the probe head to pass through and extend according to a longitudinal development axis, and the pair of first guide holes may be configured to slidably accommodate the pair of probes. A first material between the pair of first guide holes in the first guide plate may have a relative dielectric constant not greater than 6. The first material is configured to provide a compensating impedance between the pair of first guide holes, and the compensating impedance is used to improve the impedance matching when probing the device under test with the pair of probes, so as to reduce a return loss between the probe head and a device under test.

In order to at least solve the above technical problems, the present invention further provides a probe head of a probe system for testing a device under test integrated in a semiconductor wafer. The probe head may comprise a plurality of probes, and each of the plurality of probes may comprise a first end, a second end, and a probe body. The first end ends at a contact tip and is configured to abut a contact pad of the device under test. The second end ends in a contact bottom and is configured to abut a contact pad of a board of the probe system. The probe body extends between the first end and the second end according to a longitudinal development axis. The probe head may further comprise a first guide plate, the first guide plate may comprise a pair of first guide holes for a pair of probes among the plurality of probes to pass through and extend according to the longitudinal development axis, and the pair of first guide holes are configured to slidably accommodate the pair of probes. A first material between the pair of first guide holes in the first guide plate may have a relative dielectric constant not greater than 6, so as to reduce a return loss between the probe head and the device under test.

In order to at least solve the above technical problems, the present invention further provides a probe card of a probe system for testing a device under test integrated in a semiconductor wafer. The probe card may comprise a circuit board, a space transformer arranged on the circuit board, and a probe head as described above. The probe head may be arranged on the other side of the space transformer opposite to the circuit board, and a second end of each of the plurality of probes in the probe head is configured to be electrically connected with the space transformer.

In order to at least solve the above technical problems, the present invention further provides a probe system for testing a device under test integrated in a semiconductor wafer. The probe system may include a chuck, a testing apparatus, and a probe card as described above. The chuck may be used for supporting the semiconductor wafer. The testing apparatus may be electrically connected with the device under test (i.e., the object to be tested) and used for establishing an electrical test program. The probe card may be arranged in the probe system.

According to the above descriptions, the probe head and the guide plate structure thereof provided by the present invention adopt the material with low relative dielectric constant as the guide plate material between a pair of probes corresponding to a group of differential signals, thus effectively reducing the impedance fluctuation caused by the guide plate between the pair of probes, thereby further reducing the return loss between the probe head as a whole and the device under test. That is, the impedance matching between the probe head (even the probe card to which the probe head belongs) as a whole and the device under test is improved. The more groups of probe pairs for differential signals are the abovementioned mechanism provided by the present invention applied to, the higher improvement effect can be obtained.

The above content provides a basic description of the present invention, including the technical problems solved by the present invention, the technical means adopted by the present invention and the technical effects achieved by the present invention, and various embodiments of the present invention will be further exemplified in the following description.

### BRIEF DESCRIPTION OF THE DRAWINGS

Attached drawings are as follows:

FIG. 1 illustrates a probe system in which a probe head and a guide plate structure are located according to one or more embodiments of the present invention.

FIG. 2 to FIG. 9 illustrate a probe head according to one or more embodiments of the present invention.

FIG. 10 is an eye diagram when a device under test is tested based on a guide plate structure in the prior art.

FIG. 11 is an eye diagram when a device under test is tested based on a guide plate structure according to one or more embodiments of the present invention.

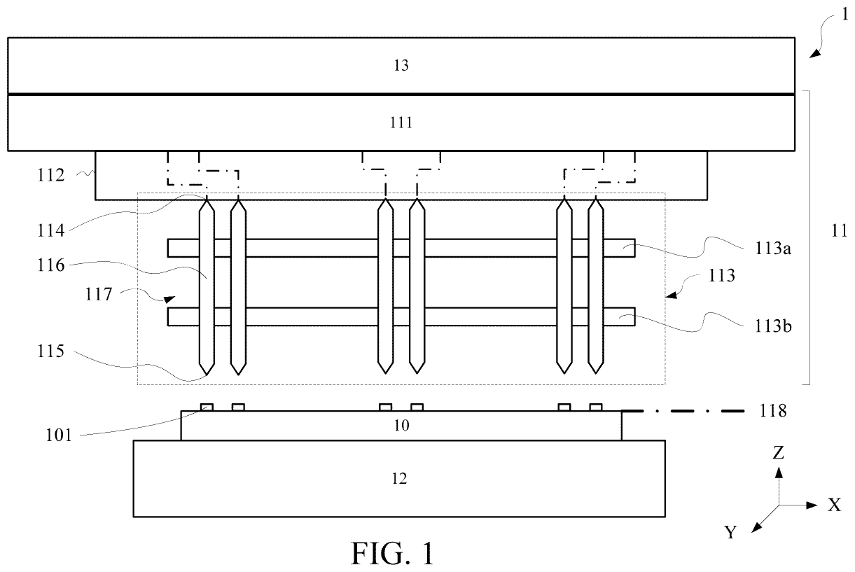

What shown in FIG. 1 to FIG. 9 and FIG. 11 are only exemplary examples for explaining embodiments of the present invention, and are not intended to limit the scope claimed in the present invention.

### DETAILED DESCRIPTION OF THE INVENTION

The following embodiments are not intended to limit the invention to be claimed to a specific environment, application, structure, process, or situation. In the attached drawings, elements unrelated to the invention to be claimed will be omitted. In the attached drawings, dimensions of and dimensional scales among individual elements are provided only as exemplary examples, and are not intended to limit the invention to be claimed. The same element symbols in the follow description may refer to the same elements unless otherwise specified.

Terminology described herein is only for ease of description of the content of the embodiments, and is not intended to limit the invention to be claimed. Unless otherwise specified clearly, singular forms “a” or “an” shall be deemed to include the plural forms as well. Terms such as “including”, “comprising” and “having” are used to specify the existence of features, integers, steps, operations, elements, components and/or groups stated after the terms, but do not exclude the existence or addition of one or more other additional features, integers, steps, operations, elements, components and/or groups or the like. The term “and/or” is used to indicate any one or all combinations of one or more related items enumerated. When the terms “first”, “second” and “third” are used to describe elements, the terms are not intended to limit but only distinguish these described elements. Therefore, for example, a first element may also be named as a second element without departing from the spirit or scope of the invention to be claimed.

Please refer to FIG. 1, which demonstrates a probe system 1. The probe system 1 may at least comprise a probe card 11 and a chuck 12. The probe card 11 may be used to electrically connect and/or mechanically contact a device under test 10 and to test the electrical performance of the device under test 10. The probe card 11 may be configured to test the device under test 10. The device under test 10 may be semiconductor wafers. The chuck 12 may be used to support the device under test 10 for probing by the probe card 11. The device under test 10 may comprise one or more contact pads (e.g., a contact pad 101 shown in FIG. 1) such that the probe tip is configured to contact the one or more contact pads during testing of the device under test 10.

The probe card 11 may comprise a circuit board 111, a space transformer 112, and a probe head 113. The space transformer 112 may be disposed on the circuit board 111, and the probe head 113 may be disposed on the space transformer 112. The probe head 113 may basically comprise a plurality of probes and at least one guide plate, and one end of each probe may be electrically connected with the circuit board 111 through the space transformer 112, and the other end of each probe may be in contact with a contact pad (e.g., a metal pad or a conductor bump) on the device under test 10 during testing. It shall be noted that the above-mentioned space transformer 112 is described as being disposed on the circuit board 111 simply according to the conventional dimensional relationship between the space transformer 112 and the circuit board 111, and it is not intended to limit that the space transformer 112 must be located above the circuit board 111 in the physical sense.

The testing apparatus 13 may perform various test procedures and/or communicate test information to the device under test through the probe card 11. The testing apparatus 13 may be, for example, a test head of a prober. In some test methods, there may be a Loopback test, the Loopback test uses the device under test 10 itself to generate a required high-frequency test signal, and the high-frequency test signal after passing through the probe card 11 is sent back to the device under test 10 for testing so as to determine whether the device under test works normally.

The circuit board 111 comprises a wafer side and a tester side. The wafer side of the circuit board 111 and the tester side of the circuit board 111 are disposed opposite to each other, and the tester side of the circuit board 111 is used for connecting a testing apparatus. In this embodiment, when the probe card 11 is used in the testing apparatus, the wafer side may be the lower side of the circuit board 111 which may face the space transformer 112 and/or the device under test, while the tester side may be the upper side of the circuit board 111 which may face away from the device under test and/or face the testing apparatus. In this embodiment, a general printed circuit board is adopted as the circuit board 111, the circuit board 111 has a top surface, a bottom surface and a variety of signal lines located therein, and contact pads electrically connected with the signal lines are formed on the top surface and the bottom surface. The contact pad on the top surface of the circuit board 111 is touched through the pogo pin of the testing apparatus. The test signal of the testing apparatus may be transmitted to the bottom surface of the circuit board 111 through the signal lines described above.

The space transformer 112 also comprises a wafer side and a tester side. Here it shall be noted that, the space transformer 112 may be composed of a multilayer circuit board. The tester side of the space transformer 112 is connected to the wafer side of the circuit board 111. In this embodiment, when the probe card 11 is used in the testing apparatus, the wafer side may be the lower side of the space transformer 112 which may face the probe head 113 and/or the device under test, while the tester side may be the upper side of the space transformer 112 which may face away from the device under test, face the circuit board 111, and/or face the testing apparatus. In this embodiment, the space transformer 112 comprises a multilayer organic (MLO) carrier or a multilayer ceramic (MLC) carrier, and the material thereof may be adjusted according to actual needs, which is not limited in the present invention. The space transformer 112 is provided with a variety of signal lines therein, and contact pads electrically connected with the internal signal lines thereof are formed on the top surface and the bottom surface of the space transformer 112, and the spacing between contact pads on the top surface is greater than the spacing between the contact pads on the bottom surface. The space transformer 112 is mechanically arranged on and electrically connected with the wafer side of the circuit board 111 (i.e., the bottom surface of the circuit board 111) and is located below the circuit board 111 so that the contact pads on the top surface of the space transformer 112 may be electrically connected with the contact pads on the bottom surface of the circuit board 111, and thus the signal lines inside the space transformer 112 are electrically connected with the signal lines of the circuit board 111. Here it shall be noted that, the space transformer 112 may also be mechanically arranged on and/or electrically connected with the wafer side of the circuit board 111 indirectly through another carrier (for example, a raised board) disposed between the space transformer 112 and the circuit board 111.

The probe head 113 may be mechanically arranged on and/or electrically connected with the wafer side of the space transformer 112. As shown in FIG. 1, the probe head 113 is in the form of a probe holder, and the probe head 113 comprises an upper guide plate unit 113a, a lower guide plate unit 113b and a plurality of probes. The upper guide plate unit 113a may comprise at least one upper guide plate, and the at least one upper guide plate may be provided with a plurality of upper guide holes. The lower guide plate unit 113b may comprise at least a lower guide plate, and the at least lower guide plate may be provided with a plurality of lower guide holes. The upper guide plate unit 113a and the lower guide plate unit 113b may be vertically arranged opposite to each other along a longitudinal development axis (e.g., substantially along the direction of the coordinate axis Z (hereinafter referred to as “Z axis” for short) of the local reference system in FIG. 1). Each probe passes through one of the plurality of upper guide holes and one of the plurality of lower guide holes.

As shown in FIG. 1, each probe may comprise a first end (e.g., an end 115 in FIG. 1), a second end (e.g., an end 114 in FIG. 1) and a probe body (e.g., a probe body 116 in FIG. 1) located between the first end and the second end. The first end may be the pinhead which ends at a contact tip, and the first end may be configured to abut a contact pad of the device under test 10 integrated in the semiconductor wafer. For example, the end 115 shown in FIG. 1 is configured to abut a contact pad 101 of the device under test 10. The pin bottom of each probe may pass through the upper guide hole of the upper guide plate unit to be electrically connected with the space transformer 112. The second end may be the pin bottom which ends at a contact bottom, and the second end may be configured to abut a contact pad of the space transformer 112. The probe body may be a pin body extending basically along the longitudinal development axis between the first end and the second end. The pinhead of each probe is used to make electrical contact with the device under test. The pinhead of each probe may be configured for electrical and/or contact communication with the corresponding contact pad of the device under test. In some examples, communication means that the probe may be configured to transmit test signals of the probe card 11 to the device under test 10 and/or receive signals from the device under test 10.

Many embodiments of the present invention relate to different embodiments of the probe head 113 and the guide plate structure in the probe head 113. It shall be noted, however, that although the probes and the guide plate structures in various embodiments of the present invention may vary slightly, the plurality of probes contained in the probe heads in various embodiments generally may all include at least one probe pair, and each probe pair may be used to transmit a group of differential signals, that is, the probe pair is a differential pair. In a preferred embodiment of the present invention, the differential pair is used to transmit differential signals. That is, two single-ended signal lines (e.g., a P line and a N line) are used to connect TX+ and RX+, and TX− and RX− respectively to transmit signals at the same time, and these two signals have the same signal voltage amplitude but opposite signal phases (i.e., one with the positive signal phase and the other with the negative signal phase). That is, these two signal lines are mutually referenced, in which the P line refers to the N line, the N line refers to the P line, and the P line and the N line are ideally mutual reference loops.

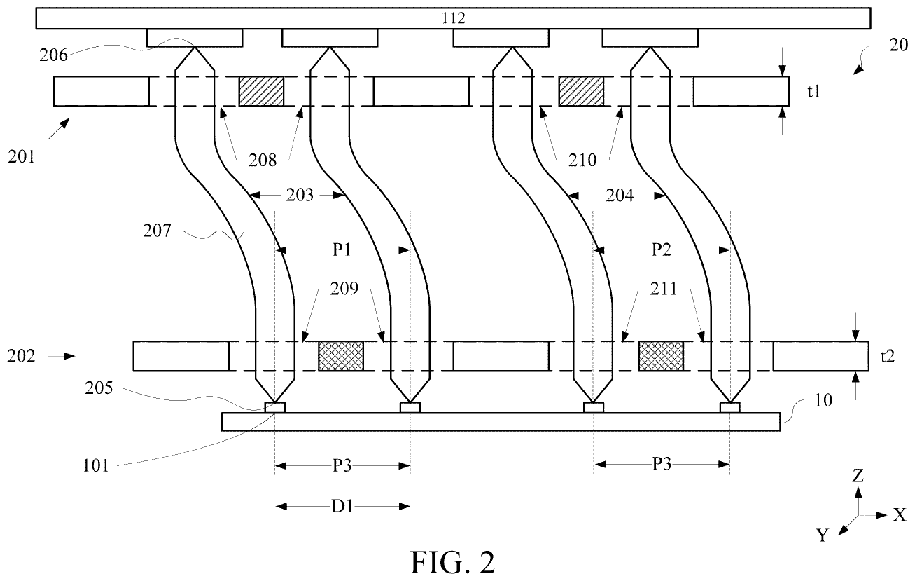

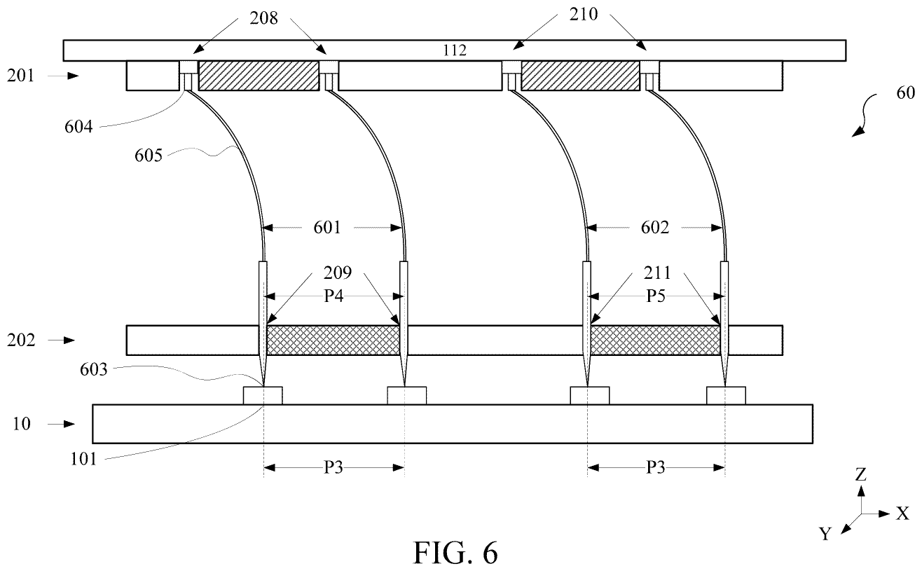

Additionally, although the probes are depicted as straight probes in FIG. 1, this is not a direct limitation on the type of probes applicable to the present invention. In fact, the probes applicable to the present invention may at least include straight probes (as illustrated in FIG. 1 to FIG. 5, wherein FIG. 2 to FIG. 5 illustrate the assembled state of a straight probe offset from a flat plate) or pre-bent probes (as illustrated in FIG. 6 to FIG. 9) or the like form. More specifically, the straight probe may be, for example, a Forming wire (FW), a MEMS wire (MW), or a pogo pin or the like. The pre-bent probe may be, for example, a Cobra probe or a MEMS body pre-bent forming wire or the like.

The so-called vertical probe head type basically comprises a plurality of contact probes held by at least one pair of flat plates (guide plates) or flat plate-like guides which are substantially parallel to each other. The flat plate-like guides may be provided with specific holes (e.g., guide holes or guide holes) and may be configured to be separated from each other by a specific distance, so as to reserve a free space or an air gap 117 for the contact probe to move and possibly deform. This pair of guide plates especially comprises an upper guide plate and a lower guide plate, both of which are provided with individual guide holes, and the contact probes pass through the guide holes in an axially slidable manner, and the probes are usually made of special metals with good electrical and mechanical properties. A good connection between the contact probe and the contact pad of the device under test is ensured by pressing the test head on the component itself. During pressurized contact, the probe may be slidably contacted inside the guide holes in the upper and lower guide plates, which causes bending in the air gap between the two guide plates and causing sliding inside the guide holes.

In addition, the bending of the contact probes (e.g., the forming wire or the MEMS wire among straight probes as illustrated in FIG. 2 to FIG. 5) in the air gap may be assisted by properly configuring the probes themselves (such as the pre-bent probes as illustrated in FIG. 6 to FIG. 9) or the guide plates thereof. In FIG. 2 to FIG. 5, in order to simplify the explanation, only some contact probes among a plurality of probes usually contained in a test head are depicted in the figure, and the test head is of the so-called offset flat plate type (which is suitable for the forming wire or the MEMS wire among the straight probes). Specifically, the respective centers of the upper guide holes and the lower guide holes corresponding to each other may be misaligned with each other, that is, the center connecting line between the upper guide hole and the lower guide hole is not parallel to a longitudinal direction. The longitudinal direction may be direction parallel to the Z axis in the local reference system of the drawing, and it is perpendicular to a reference plane 118. The reference plane 118 may correspond to a horizontal development plane of the guide plates. Accordingly, the contact probes accommodated in the guide holes of the upper guide plate and the lower guide plate are deformed with respect to a longitudinal development axis thereof (corresponding to the Z-axis direction of the local reference system of the drawing), and the longitudinal development axis is set to be perpendicular to the reference plane 118. The upper guide plate and the lower guide plate may be parallel to each other and extend along the reference plane 118, and the semiconductor wafer, the device under test 10 and the plates of the space transformer 112 may also develop along the reference plane 118.

When the probe in the vertical probe head is of a pre-bent probe type, e.g., in the example of a test head made of Cobra in the prior art, as shown in FIG. 6 to FIG. 9, the contact probe will have a pre-deformed configuration with an offset between the contact tip portion and the contact bottom portion which have been defined in the placement conditions of the probe head. Especially in this example, the contact probe comprises a pre-deformed part, which may assist the proper bending of the contact probe even when the test head is not in contact with the device under test. The contact probe is further deformed during its operation, i.e., when it is pressed to contact the device under test. It shall be noted that for proper probe head operation, the contact probe may have proper freedom of axial movement inside the guide holes. In this way, these contact probes may also be extracted and replaced when a single probe fails, without being forced to replace the entire probe head. The freedom of axial movement (especially when the probe slides inside the guide hole) is in contrast with the normal safety requirements of the probe head during its operation.

Please refer to FIG. 2. A first embodiment of the present invention is a probe head 20 and a guide plate structure thereof. The probe head 20 may be used to replace the probe head 113 shown in FIG. 1. The probe head 20 may be mechanically arranged on and/or electrically connected with the wafer side of the space transformer 112. The probe head 20 may comprise an upper guide plate unit, a lower guide plate unit and a plurality of probes. The upper guide plate unit may comprise at least one upper guide plate, such as an upper guide plate 201 shown in FIG. 2. The lower guide plate unit may comprise at least a lower guide plate, such as a lower guide plate 202 shown in FIG. 2. Hereinafter, the at least one upper guide plate included in the upper guide plate unit and the at least one lower guide plate included in the lower guide plate unit will be exemplified by the upper guide plate 201 and the lower guide plate 202, respectively.

The upper guide plate 201 may be provided with a plurality of upper guide holes, while the lower guide plate 202 may be provided with a plurality of lower guide holes. The upper guide plate 201 and the lower guide plate 202 may be vertically arranged opposite to each other along a longitudinal development axis (substantially along the Z-axis direction of the local reference system in the figure).

The probe head 20 may further comprise a plurality of probes, such as a probe pair 203 and a probe pair 204 shown in FIG. 2 for transmitting differential signals in pairs. Each probe passes through one of the plurality of upper guide holes and one of the plurality of lower guide holes. In addition, each probe may comprise a first end, and the first end may end at a contact tip and may be configured to abut a contact pad of the device under test 10. For example, an end 205 shown in FIG. 2 is configured to abut a contact pad 101 of the device under test 10. Each probe may further comprise a second end (e.g., an end 206 shown in FIG. 2), and the second end may end at a contact bottom and may be configured to abut a corresponding contact pad of the space transformer 112.

Each probe may further comprise a probe body extending between the first end and the second end according to a longitudinal development axis. For example, a probe body 207 shown in FIG. 2 extends between the end 205 and the end 206 according to a longitudinal development axis. Each probe body may have a transverse diameter, which is an extension of the cross section of the probe and/or a maximum transverse dimension of a cross section. The cross section is not necessarily a circle, and may be taken from a plane perpendicular to the longitudinal development axis (that is, perpendicular to the Z-axis direction in the figure). The probe body preferably has a square or rectangular cross section. According to some embodiments of the present invention, the probe may be a probe that is called a “buckling beam” in the art. That is, the probe has a constant and preferably square or rectangular cross section over its entire length, wherein the probe body is deformed and suitable for bending at a substantially central position, and thus the probe body is further deformed during the testing of the device under test.

The upper guide plate 201 and the lower guide plate 202 may be separated by a distance, and may each comprise a plurality of guide holes corresponding to the plurality of probes so as to slidably accommodate a probe in each guide hole, and the guide holes accommodating the same probe in the upper guide plate 201 and the lower guide plate 202 correspond to each other. In practical application, the upper guide plate 201 and the lower guide plate 202 may be offset on the XY plane to assist the contact probe to bend in the air gap. In FIG. 2, in order to simplify the explanation, only some of multiple probes usually included in a probe head 20 are depicted in the figure.

As shown in FIG. 2, the upper guide plate 201 may comprise a guide-hole pair 208, while the lower guide plate 202 may comprise a guide-hole pair 209. The guide-hole pair 208 and the guide-hole pair 209 may be used to accommodate the probe pair 203. Similarly, the upper guide plate 201 may further comprise another guide-hole pair 210, while lower guide plate 202 may comprise another guide-hole pair 211, and the guide-hole pair 210 and the guide-hole pair 211 may be used to accommodate the probe pair 204. In some embodiments, each guide hole in the guide-hole pair 208 and/or the guide-hole pair 209 may be substantially circular. In some embodiments, each guide hole in the guide-hole pair 208 and/or the guide-hole pair 209 may be substantially polygonal, such as rectangular, trapezoidal, parallelogram-shaped or the like. In addition, in some embodiments where the guide holes are polygonal, the guide-hole pair 208 and/or the guide-hole pair 209 may also each be arranged with the shortest sides of the polygons opposite to each other. That is, the guide-hole pair 208 and/or the guide-hole pair 209 may each be arranged with the width sides opposite to each other when taking the rectangular guide holes as an example.

In this embodiment, the probe pair 203 and/or the probe pair 204 are a differential pair that transmits a group of differential signals. In order to reduce the impedance fluctuation caused when the probe pair 203 transmits the differential signals, the area between the guide-hole pair 209 in the lower guide plate 202 (indicated by cross lines in the figure) may have a first material and/or the area between the guide-hole pair 208 in the upper guide plate 201 (indicated by diagonal lines in the figure) may have a second material. Similarly, the area between the guide-hole pair 211 in the lower guide plate 202 (indicated by cross lines in the figure) may have the first material and/or the area between the guide-hole pair 210 in the upper guide plate 201 (indicated by diagonal lines in the figure) may have the second material. In FIG. 2, although the area between the guide-hole pair 209 is shown as extending along the direction of a coordinate axis X (hereinafter referred to as “X axis” for short) of the local reference system, in some embodiments, the area between the guide-hole pair 209 may also extend along the direction of a coordinate axis Y (hereinafter referred to as “Y axis” for short) of the local reference system. That is, when the differential pairs are arranged at intervals along the X-axis direction and the buckling direction of the probe is the X-axis direction (as illustrated in FIG. 2), the area between the guide-hole pair 209 may be defined as extending along the X-axis direction; and when the differential pairs are arranged at intervals along the Y-axis direction and the buckling direction of the probe is still the X-axis direction, the area between the guide-hole pair 209 may be defined as extending along the Y-axis direction.

At least one of the first material and the second material may have a relative dielectric constant not greater than 6, so as to reduce a return loss between the probe head 20 and the device under test 10, that is, to improve the degree of impedance matching between the probe head 20 and the device under test 10. That is, the first material and the second material are configured to provide a compensating impedance between the guide-hole pairs 208, 209, 210 and 211, and the compensating impedance is used to improve the impedance matching when probing the device under test with the probe pairs 203 and 204. Furthermore, in some embodiments, the first material in the lower guide plate 202 and/or the second material in the upper guide plate 201 may even have a relative dielectric constant not greater than 4. For example, the first material and the second material may be ceramics, porous ceramics, ceramic matrix composite or engineering plastics respectively, and the second material may be different from the first material in some embodiments.

In some embodiments, the first material and/or the second material described above may be a composite material. That is, the first material and/or the second material with a relative dielectric constant not greater than 6 (or even not more than 4) may be composed of multiple materials.

In some embodiments, a thickness t2 of the lower guide plate 202 may be not less than a thickness t1 of the upper guide plate 201. For example, when the thickness t2 of the lower guide plate 202 is greater than the thickness t1 of the upper guide plate 201, better support can be obtained when the probe slides and moves in the guide-hole pair 209 and the guide-hole pair 211, so that the probe can slide and move up and down in the guide-hole pair 209 and the guide-hole pair 211 more smoothly. However, in some embodiments, the thickness of the upper guide plate 201 may be not less than that of the lower guide plate 202.

The probe pair 203, the probe pair 204, and other probes in the probe head 20 may all be in the form of straight probes. In some embodiments, the spacing between the corresponding centers of the probe pair 203 may have a first relative distance P1. The first relative distance P1 may range from 80 micrometers to 220 micrometers, and preferably from 100 micrometers to 130 micrometers. Similarly, in some embodiments, the spacing between the corresponding centers of the probe pairs 204 may have a second relative distance P2. The second relative distance P2 may also range from 80 micrometers to 220 micrometers, and preferably from 100 micrometers to 130 micrometers.

Specifically, the first relative distance P1 may be a center spacing corresponding to the first end (the contact tip) of the probe pair 203 or a center spacing corresponding to the second end (the contact bottom) of the probe pair 203, and it corresponds to a center spacing of the corresponding groups of contact pads in the device under test 10. In some embodiments, the center spacing corresponding to the first end (the contact tip) of the probe pair 203 may be equal to the center spacing corresponding to the second end (the contact bottom) of the probe pair 203. Similarly, the second relative distance P2 may be a center spacing corresponding to the first end (the contact tip) of the probe pair 204 or a center spacing corresponding to the second end (the contact bottom) of the probe pair 204, and it corresponds to a center spacing of the corresponding groups of contact pads in the device under test 10. In some embodiments, the center spacing corresponding to the first end (the contact tip) of the probe pair 204 may be equal to the center spacing corresponding to the second end (the contact bottom) of the probe pair 204. In some embodiments, the center spacing of the respective groups of contact pads corresponding to the respective probe pairs in the device under test 10 may be a third relative distance P3, and the first relative distance P1 and/or the second relative distance P2 may be smaller than the third relative distance P3.

In some embodiments, the probe length of the respective probe pairs in the probe head 20 according to the longitudinal development axis may range between 3 millimeters and 7 millimeters. In some embodiments, the probe length may also be not greater than 6 millimeters or even preferably not greater than 4 millimeters.

In some embodiments, the thickness of the contact tip of each of the probe pair 203, the probe pair 204 and other probe pairs in the probe head 20 in a direction of a probe-center-connecting line (e.g., a direction D1 of a probe-center-connecting line corresponding to the probe pair 203 as illustrated in FIG. 2) corresponding to the respective probe pairs may be greater than the thickness of the remaining parts of the first end (i.e., other parts except for the contact tip) in the direction of a probe-center-connecting line, and even further greater than the thickness of the probe body (the pin body) in the direction of a probe-center-connecting line in some embodiments. In order to achieve this result, the contact tip may be thickened in the production process (for example, the contact tip is entirely covered and thickened as a whole, or the contact tip is only partially thickened in the direction of a probe-center-connecting line), but the way in which the contact tip is thickened is not limited to electroplating. For example, for MEMS wires, the thickness of the contact tip may be increased through the MEMS process. When the contact tips of the probe pairs 203, 204 are thickened, the contact areas thereof with the contact pads of the device under test will also be increased, thereby providing a more stable contact mode. Especially, when the return loss between the probe head and the device under test is reduced for impedance matching, the spacing between the corresponding centers of the probe pair 203 is reduced, that is, the first relative distance P1 is reduced to be less than the third relative distance P3, and at this point, the thickened contact tip can still normally contact the contact pad.

In some embodiments, when the probe is a pre-bent (e.g., Cobra) probe (as described later for FIG. 6 to FIG. 9), the width of the probe body may still be greater than the thickness of the thickened contact tip because the probe body is processed by stamping in the production process, so as to prevent the probe from slipping out of the guide hole of the guide plate. The thickness of the thickened contact tip may be greater than or equal to a remaining part of the first end and/or the probe body preferably by 2% to 20%, and more preferably by 10%. The increase in thickness of the thickened contact tip may range from 1 to 5 micrometers, and preferably may range from 1 to 2 micrometers. Taking the case where the contact tip is thickened (that is, the diameter is increased) by electroplating (e.g., in the case of Cobra) as an example, when the thickness of the first end of the probe is 50 micrometers, a thickness of 1 to 2 micrometers may be formed at the contact tip, and at this point, the thickness of the thickened contact tip is 52 to 54 micrometers.

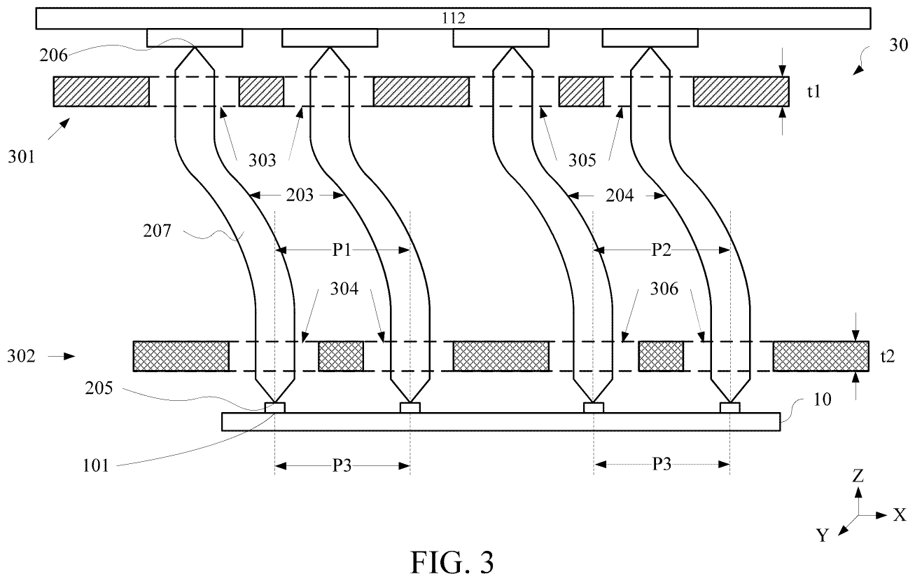

Please refer to FIG. 3. A second embodiment of the present invention is a probe head 30 and a guide plate structure thereof. In the probe head 20 shown in FIG. 2, the lower guide plate 202 and/or the upper guide plate 201 only have the first material or the second material in the area between the respective guide-hole pair. However, the probe head 30 shown in FIG. 3 differs from the probe head 20 in that an entire lower guide plate 302 included in the probe head 30 may have the first material and/or an entire upper guide plate 301 included in the probe head 30 may have the second material.

The upper guide plate 301 may comprise a guide-hole pair 303, while the lower guide plate 302 may comprise a guide-hole pair 304. The guide-hole pair 303 and the guide-hole pair 304 may also be used to accommodate the probe pair 203. Similarly, the upper guide plate 301 may further comprise another guide-hole pair 305, while the lower guide plate 302 may comprise another guide-hole pair 306, and the guide-hole pair 305 and the guide-hole pair 306 may be used to accommodate the probe pair 204.

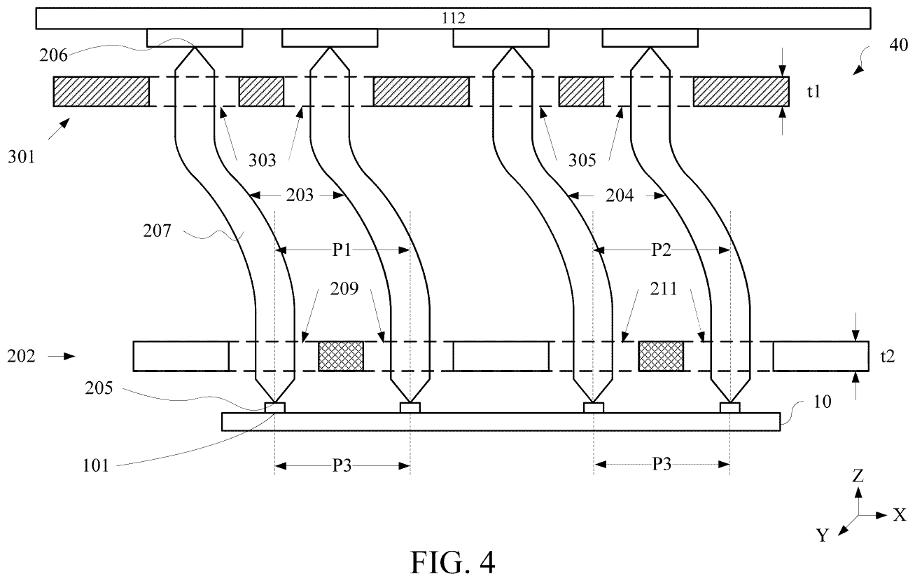

Please refer to FIG. 4. A third embodiment of the present invention is a probe head 40 and a guide plate structure thereof. The probe head PH3 differs from the probe heads 20 and 30 in that the probe head 40 may have the first material or the second material only in the area between each guide-hole pair on one included guide plate (as in the case of the upper and lower guide plates shown in FIG. 2), and may have the first material or the second material on the entirety of another included guide plate (as in the case of the upper and lower guide plates shown in FIG. 3). In other words, the distribution of the first material and the second material among the two guide plates may be different. FIG. 4 illustrates one case in which the probe head 40 may adopt the upper guide plate 301 in the probe head 30 as its upper guide plate and adopt the lower guide plate 202 in the probe head 20 as its lower guide plate.

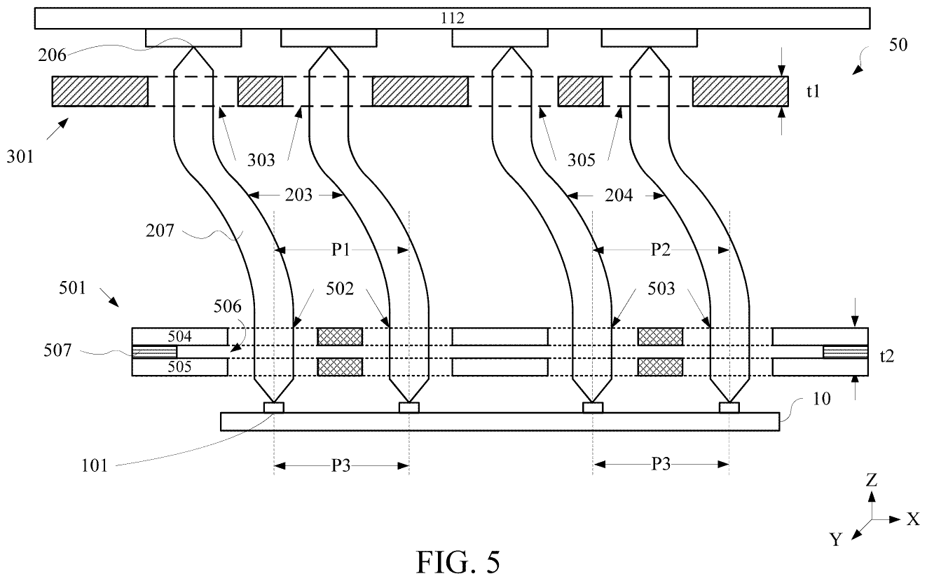

Please refer to FIG. 5. A fourth embodiment of the present invention is a probe head 50 and a guide plate structure thereof. The probe head 50 differs from other embodiments previously described in that it comprises at least one multilayer guide plate. The multilayer guide plate may have at least a first layer and a second layer, and an air layer may be interposed between the first layer and the second layer. Each probe in the probe head 50 may penetrate through the first layer, the air layer and the second layer. FIG. 5 illustrates one case in which the probe head 50 may adopt the upper guide plate 301 in the probe head 30 as its upper guide plate and may comprise a multilayer lower guide plate 501. The lower guide plate 501 may have a guide-hole pair 502, a guide-hole pair 503, a first layer 504 and a second layer 505, and an air layer 506 may be interposed between the first layer 504 and the second layer 505. The air layer 506 may be formed by separating the first layer 504 from the second layer 505 by a frame 507 (indicated by horizontal lines in the figure) of the lower guide plate 501. The guide-hole pair 502 and the guide-hole pair 503 may penetrate through the first layer, the air layer and the second layer, while the probe pair 203 and the probe pair 204 may penetrate through the guide-hole pair 502 and the guide-hole pair 503 respectively. However, the multilayer guide plate is not limited to comprising two layers, and the probe head 50 is not limited to comprising one multilayer guide plate. That is, in some embodiments, both the upper and lower guide plates of the probe head 50 may be multilayer guide plates, and each multilayer guide plate may comprise more than two layers.

In addition, in some embodiments, the multilayer guide plate may have the first material or the second material only in the area between each guide-hole pair, just like the guide plate in the probe head 20. However, in some embodiments, the multilayer guide plate may have the first material or the second material on the entirety of the first layer and the second layer, just like the guide plate in the probe head 30.

Please refer to FIG. 6. A fifth embodiment of the present invention is a probe head 60 and a guide plate structure thereof. The probes included in the probe head shown in FIG. 2 to FIG. 5 are all straight probes, while a plurality of probes included in the probe head 60 may be pre-bent probes (e.g., a probe pair 601 and a probe pair 602 shown in FIG. 6 for transmitting differential signals in pairs). Each probe passes through one of a plurality of upper guide holes and one of a plurality of lower guide holes. In addition, each probe may comprise a first end, and the first end may end at a contact tip and may be configured to abut a contact pad of the device under test 10. For example, an end 603 shown in FIG. 6 is configured to abut a contact pad 101 of the device under test 10. Each probe may further comprise a second end (e.g., an end 604 shown in FIG. 6), and the second end may end at a contact bottom and may be configured to abut a corresponding contact pad of the space transformer 112.

Each probe may further comprise a probe body extending between the first end and the second end according to a longitudinal development axis. For example, a probe body 605 shown in FIG. 6 extends between the end 603 and the end 604 according to a longitudinal development axis. Each probe body may have a transverse diameter, which is an extension of the cross section of the probe and/or a maximum transverse dimension of a cross section. The cross section is not necessarily a circle, and may be taken from a plane perpendicular to the longitudinal development axis (that is, perpendicular to the Z-axis direction in the figure). The probe body preferably has a square or rectangular cross section, and the probe body may have a flat shape because it has been processed by stamping in the production process.

The probe head 60 may comprise the upper guide plate 201 and the lower guide plate 202 in the probe head 20. Both the guide-hole pair 208 included in the upper guide plate 201 and the guide-hole pair 209 included in the lower guide plate 202 may be used to accommodate the probe pair 601. Similarly, the guide-hole pair 210 included in the upper guide plate 201 and the guide-hole pair 211 included in the lower guide plate 202 may be used to accommodate the probe pair 602.

For the guide plate structure included in the upper guide plate 201 and the lower guide plate 202 in order to reduce the impedance fluctuation caused when the probe pair 601 and the probe pair 602 transmit differential signals, reference may be made to the contents described for the probe head 20, and this will not be further described herein. In some embodiments, the spacing between the corresponding centers of the probe pair 601 may have a fourth relative distance P4. The fourth relative distance P4 may range from 80 micrometers to 220 micrometers, and preferably from 100 micrometers to 130 micrometers. Similarly, in some embodiments, the spacing between the corresponding centers of the probe pair 602 may have a fifth relative distance P5. The fifth relative distance P5 may also range from 80 micrometers to 220 micrometers, and preferably from 100 micrometers to 130 micrometers. Specifically, the fourth relative distance P4 may be a center spacing corresponding to the first end (the contact tip, e.g., the end 603 shown in FIG. 6) of the probe pair 601 or a center spacing corresponding to the second end (the contact bottom, e.g., the end 604 shown in FIG. 6) of the probe pair 601, and it corresponds to a center spacing (e.g., the third relative distance P3) of the corresponding groups of contact pads in the device under test 10. In some embodiments, the center spacing corresponding to the first end (the contact tip) of the probe pair 601 may be equal to the center spacing corresponding to the second end (the contact bottom) of the probe pair 601. Similarly, the fifth relative distance P5 may be a center spacing corresponding to the first end (the contact tip) of the probe pair 602 or a center spacing corresponding to the second end (the contact bottom) of the probe pair 602, and it corresponds to a center spacing (for example, the third relative distance P3) of the corresponding groups of contact pads in the device under test 10. In some embodiments, the center spacing corresponding to the first end (the contact tip) of the respective probe pairs may be equal to the center spacing corresponding to the second end (the contact bottom). In some embodiments, the center spacing of the respective groups of contact pads corresponding to the respective probe pairs in the device under test 10 may be a third relative distance P3, and the fourth relative distance P4 and/or the fifth relative distance P5 may be smaller than the third relative distance P3.

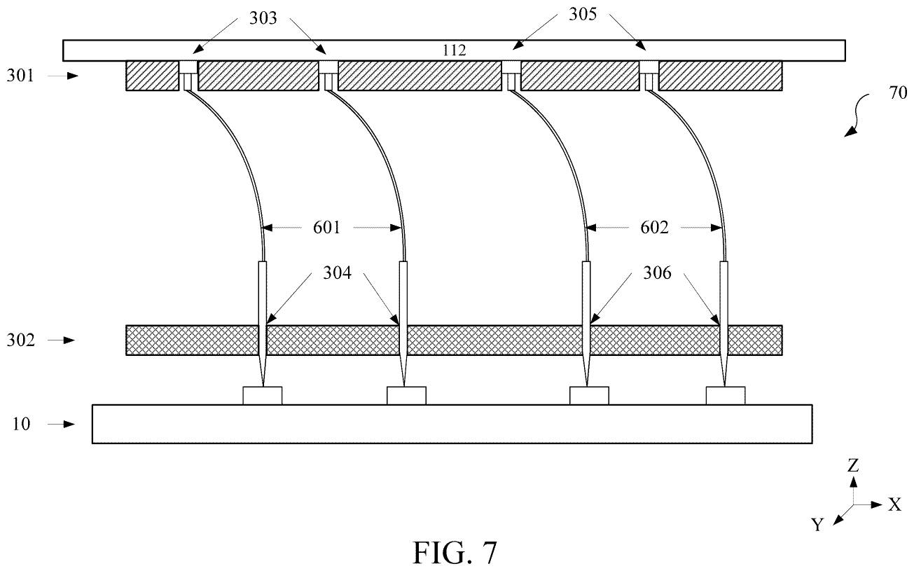

Please refer to FIG. 7. A sixth embodiment of the present invention is a probe head 70 and a guide plate structure thereof. In the probe head 60 shown in FIG. 6, the lower guide plate 202 and/or the upper guide plate 201 have the first material or the second material only in the areas between the respective guide-hole pairs. However, the probe head 70 differs from the probe head 60 in that, the probe head 70 may comprise the upper guide plate 301 and the lower guide plate 302 described previously for the probe head 30, wherein the whole lower guide plate 302 may have the first material and/or the whole upper guide plate 301 may have the second material.

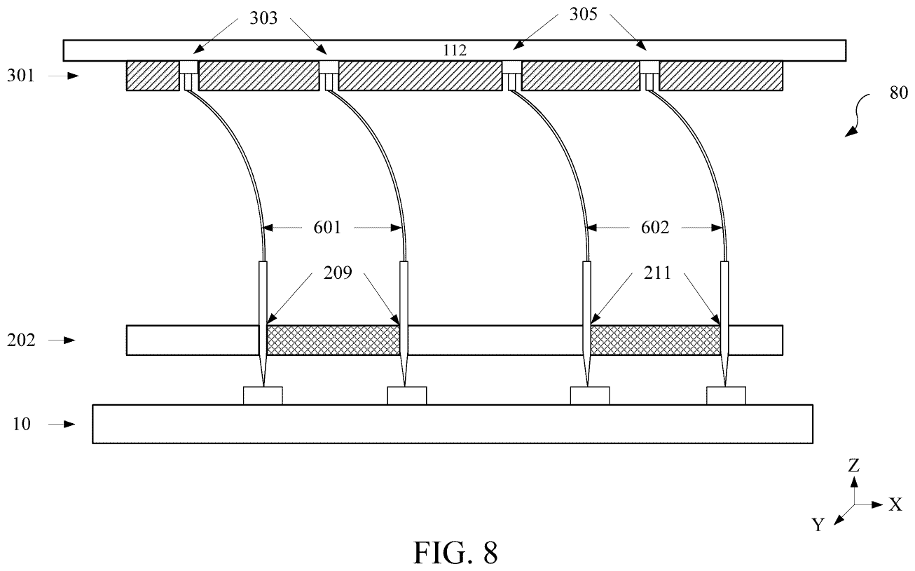

Please refer to FIG. 8. A seventh embodiment of the present invention is a probe head 80 and a guide plate structure thereof. Similar to the probe head 40, the probe head 80 differs from the probe heads 60 and 70 in that the probe head 80 may have the first material or the second material only in the area between each guide-hole pair on one included guide plate, and may have the first material or the second material on the entirety of another included guide plate. In other words, the distribution of the first material and the second material among the two guide plates may be different. FIG. 8 illustrates one case in which the probe head 80 may adopt the upper guide plate 301 previously described for the probe head 30 as its upper guide plate and adopt the lower guide plate 202 previously described for the probe head 20 as its lower guide plate.

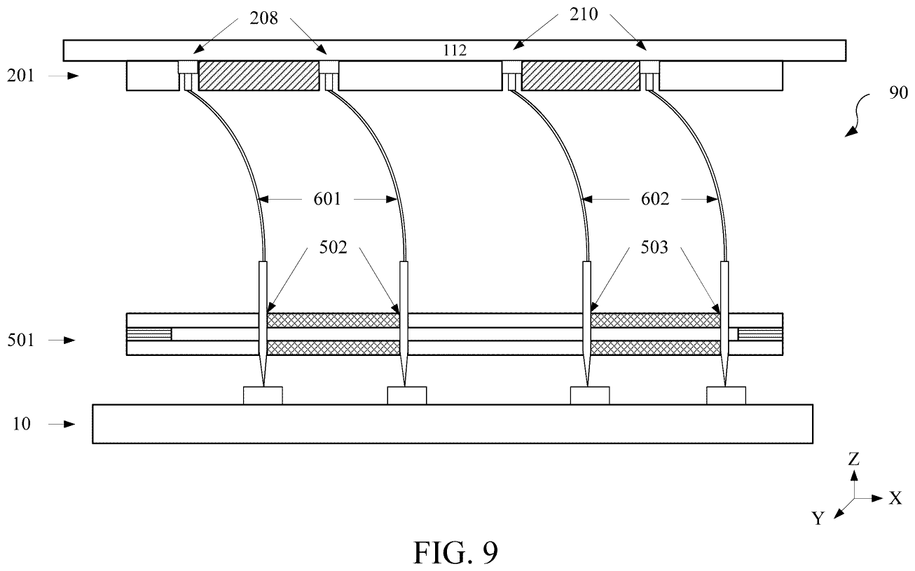

Please refer to FIG. 9. An eighth embodiment of the present invention is a probe head 90 and a guide plate structure thereof. The probe head 90 differs from the aforementioned fifth to seventh embodiments in that it comprises at least one multilayer guide plate. FIG. 9 illustrates one case in which the probe head 90 may adopt the upper guide plate 201 previously described for the probe head 20 as its upper guide plate and may adopt the lower guide plate 501 previously described for the probe head 50 as its lower guide plate. However, the probe head 90 is not limited to only comprising one multilayer guide plate. That is, in some embodiments, both the upper and lower guide plates of the probe head 90 may be multilayer guide plates. The multilayer guide plate may have a first layer and a second layer, and an air layer may be interposed between the first layer and the second layer. Each probe in the probe head 90 may penetrate through the first layer, the air layer and the second layer.

In addition, in some embodiments, the multilayer guide plate may have the first material or the second material only in the area between the respective guide-hole pairs, just like the guide plates in the probe head 20 the probe head 60. However, in some embodiments, the multilayer guide plate may also have the first material or the second material on the entirety of the first layer and the second layer, just like the guide plates in the probe head 30 and the probe head 70.

For the technical requirements as described above for the prior art, both electrical and mechanical characteristics should be considered during the designing of the probe head. In particular, the guide plate in the probe head needs to bear the force generated by elements such as the probe and/or the space transformer during the test, and thus it is required to meet the requirements of both electrical and mechanical characteristics during the test as much as possible, so as to avoid the damage (for example, the cracking of the guide hole, or chipping due to friction during the test) caused by the force exerted by the probe on the wall of the guide hole after the assembly is offset from the flat plate, which otherwise would affect the result of the testing. Therefore, after considering both improving the degree of impedance matching between the probe head 20 and the device under test 10 and improving the mechanical characteristics of the guide plate, the present invention proposes a solution of making the material of the guide plate have a relative dielectric constant not greater than 6 (or even not more than 4). In addition, in some embodiments, especially when the device under test needs high-frequency/high-speed testing, in order to take both the electrical and mechanical characteristics of the guide plate into account, the probe head form of a guide plate material with a relative dielectric constant not greater than 6 (or even not more than 4) in combination with a pre-bent probe (such as a Cobra probe or a MEMS body pre-bent forming wire, etc.) may be selected. Because offset of the guide plates are not required for the pre-bent probe, the force exerted by the probe on the wall of the guide hole may be greatly reduced. In this case, the electrical requirements for high-frequency/high-speed testing can be met, and meanwhile the requirements for mechanical characteristics of the guide plates can be slightly reduced.

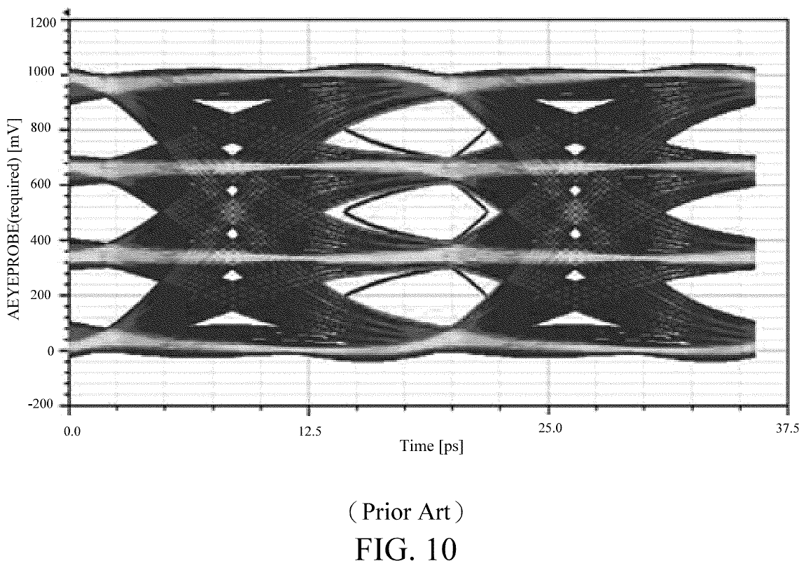

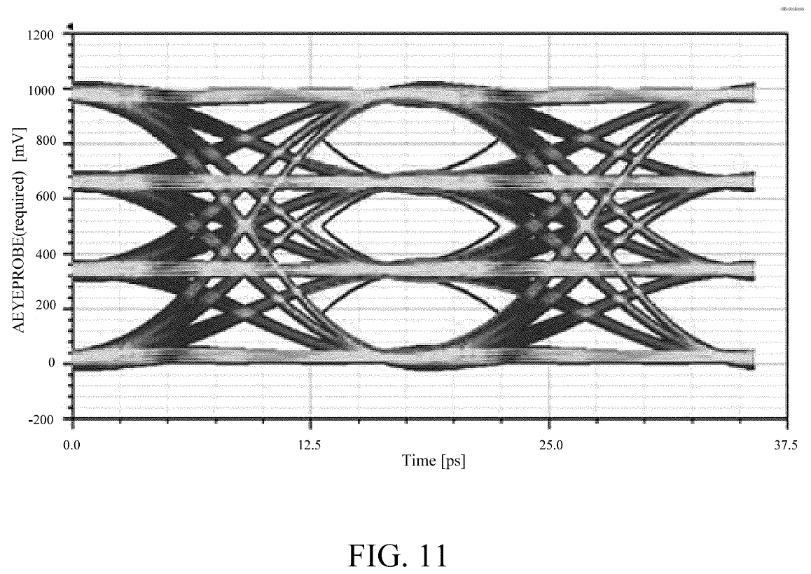

Next, please refer to FIG. 10 and FIG. 11 together. FIG. 10 is an eye diagram when a device under test is tested based on a guide plate structure in the prior art (i.e., without using a material with a low relative dielectric constant), and FIG. 11 is an eye diagram when a device under test is tested based on a guide plate structure according to one or more embodiments of the present invention (i.e., using a material with a low relative dielectric constant generally speaking). In FIG. 10, the eye height is about 188 millivolts (mV) and the eye width is about 7.82 picoseconds (ps). In FIG. 11, the eye height is 252 millivolts and the eye width is about 9.10 picoseconds. As compared to FIG. 10, the eye height in FIG. 11 is improved by 1.34 times, and the eye width is improved by 1.16 times. As can be clearly seen by comparing the two figures, the material with a low relative dielectric constant provided according to the present invention is used as the guide plate material between a pair of probes corresponding to a group of differential signals, which effectively reduces the impedance fluctuation caused by the guide plate between the pair of probes, thereby reducing the return loss between the probe head as a whole and the device under test. That is, the impedance matching between the probe head (even the probe card to which the probe head belongs) as a whole and the device under test is improved, thereby improving the signal integrity.

The above disclosure is related to the detailed technical contents and inventive features thereof. People of ordinary skill in the art may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

1. A guide plate structure of a probe head of a probe system for testing a device under test integrated in a semiconductor wafer, comprising:
a first guide plate, comprising a pair of first guide holes for a pair of probes of the probe head to pass through and extend according to a longitudinal development axis, and the pair of first guide holes being configured to slidably accommodate the pair of probes;
wherein a first material between the pair of first guide holes in the first guide plate has a relative dielectric constant not greater than 6, the first material is configured to provide a compensating impedance between the pair of first guide holes, and the compensating impedance is used to improve impedance matching when probing the device under test with the pair of probes, so as to reduce a return loss between the probe head and the device under test.

2. The guide plate structure of claim 1, further comprising:
a second guide plate, being separated from the first guide plate by a distance along the longitudinal development axis and comprising a pair of second guide holes corresponding to the pair of first guide holes for the pair of probes of the probe head to pass through;
wherein a second material between the pair of second guide holes in the second guide plate has a relative dielectric constant not greater than 6, the second material is configured to provide a compensating impedance between the pair of second guide holes, and the compensating impedance is used to improve the impedance matching when probing the device under test with the pair of probes, so as to reduce the return loss between the probe head and the device under test.

3. The guide plate structure of claim 2, wherein the first guide plate and the second guide plate respectively have a thickness along the longitudinal development axis, the thickness of the first guide plate is not less than that of the second guide plate, and the first guide plate is arranged closer to the device under test than the second guide plate.

4. The guide plate structure of claim 1, wherein two guide holes in the pair of first guide holes are arranged with the shortest sides opposite to each other.

5. The guide plate structure of claim 2, wherein both the two guide holes comprised in the pair of first guide holes and two guide holes comprised in the pair of second guide holes are arranged with the shortest sides opposite to each other.

6. The guide plate structure of claim 5, wherein both of the two guide holes in the pair of first guide holes are substantially rectangular.

7. The guide plate structure of claim 6, wherein each guide hole among the pair of first guide holes and the pair of second guide holes is substantially rectangular.

8. The guide plate structure of claim 1, wherein the first material with a relative dielectric constant not greater than 6 is used to reduce impedance fluctuation caused by the first guide plate at a part between the pair of first guide holes, thereby reducing the return loss between the probe head and the device under test.

9. The guide plate structure of claim 2, wherein the first material with a relative dielectric constant not greater than 6 is used to reduce the impedance fluctuation caused by the first guide plate at a part between the pair of first guide holes, and the second material with a relative dielectric constant not greater than 6 is used to reduce the impedance fluctuation caused by the second guide plate at a part between the pair of second guide holes, thereby reducing the return loss between the probe head and the device under test.

10. The guide plate structure of claim 1, wherein the entire first guide plate has the same first material.

11. The guide plate structure of claim 2, wherein the entire first guide plate has the same first material and the entire second guide plate has the same second material.

12. The guide plate structure of claim 1, wherein the first material between the pair of first guide holes in the first guide plate has a relative dielectric constant not greater than 4.

13. The guide plate structure of claim 2, wherein the first material between the pair of first guide holes in the first guide plate has a relative dielectric constant not greater than 4, and the second material between the pair of second guide holes in the second guide plate has a relative dielectric constant not greater than 4.

14. The guide plate structure of claim 1, wherein the first guide plate has a first layer and a second layer with an air layer interposed between the first layer and the second layer, and the pair of probes penetrate through the first layer, the air layer and the second layer.

15. The guide plate structure of claim 2, wherein each of the first guide plate and the second guide plate has a first layer and a second layer with an air layer interposed between the first layer and second layer, and the pair of probes penetrate through the first layer, the air layer and the second layer.

16. The guide plate structure of claim 1, wherein the first material with a relative dielectric constant not greater than 6 is any one of, or any combination of, ceramic, porous ceramic, ceramic matrix composite, and engineering plastic.

17. The guide plate structure of claim 2, wherein the first material with a relative dielectric constant not greater than 6 is any one of, or any combination of, ceramic, porous ceramic, ceramic matrix composite, and engineering plastic, and the second material with a relative dielectric constant not greater than 6 is any one of, or any combination of ceramic, porous ceramic, ceramic matrix composite, and engineering plastic.

18. A probe head of a probe system for testing a device under test integrated in a semiconductor wafer, comprising:
a plurality of probes, each probe comprising:
a first end, ending at a contact tip and being configured to abut a contact pad of the device under test;
a second end, ending at a contact bottom and being configured to abut a contact pad of a board of the probe system; and
a probe body, extending between the first end and the second end according to a longitudinal development axis; and
a guide plate structure of claim 1.

19. The probe head of claim 18, wherein an interval between the pair of probes ranges from 80 micrometers to 220 micrometers, and preferably from 100 micrometers to 130 micrometers.

20. The probe head of claim 18, wherein a length of the pair of probes is not greater than 6 millimeters, and preferably not greater than 4 millimeters.

21. The probe head of claim 18, wherein a thickness of the contact tip of each of the pair of probes in a corresponding direction of a probe-center-connecting line is greater than a thickness of a remaining part of the first end in the direction of a probe-center-connecting line or a thickness of the probe body in the direction of a probe-center-connecting line.

22. The probe head of claim 21, wherein the thickness of the contact tip of each of the pair of probes is greater than the thickness of the remaining part of the first end in the direction of a probe-center-connecting line or the thickness of the probe body in the direction of a probe-center-connecting line by 2% to 20%.

23. The probe head of claim 18, wherein the pair of probes is used for transmitting or receiving differential signals.

24. The probe head of claim 23, wherein the plurality of probes are all straight probes, and a probe spacing of each of a plurality of pairs of probes among the plurality of probes is smaller than a center spacing of two corresponding contact pads in the device under test, the plurality of pairs of probes comprising the pair of probes.

25. The probe head of claim 18, wherein the pair of probes are straight probes or pre-bent probes.

26. A probe card of a probe system for testing a device under test integrated in a semiconductor wafer, comprising:
a circuit board;
a space transformer arranged on the circuit board; and
a probe head of claim 18, being arranged on the other side of the space transformer opposite to the circuit board, and the second end of each of the plurality of probes in the probe head is configured to be electrically connected with the space transformer.

27. A probe system for functional testing of a device under test integrated in a semiconductor wafer, comprising:
a chuck for supporting the semiconductor wafer;
a testing apparatus, being electrically connected with the device under test for establishing an electrical testing program; and
a probe card of claim 26, being provided in the probe system.
